(19) United States
(12) Patent Application Publication
(10) Pub. No.: US 2023/0299767 A1
(43) Pub. Date: Sep. 21, 2023

(54) SEMICONDUCTOR DEVICE AND METHOD FOR CONTROLLING SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takenori YASUZUMI, Yokohama Kanagawa (JP); Kohei HASEGAWA, Yokohama Kanagawa (JP); Tsuguhiro TANAKA, Ibo Hyogo (JP); Shusuke KAWAI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/168,156

(22) Filed: Feb. 13, 2023

(30) Foreign Application Priority Data
Mar. 16, 2022 (JP) 2022-041434

(51) Int. Cl. H03K 17/687

(52) U.S. Cl. CPC H03K 17/687; H01L 29/0634

(57) ABSTRACT

According to one embodiment, a semiconductor device includes an n-layer and a p-layer arranged in a vertical trench structure in a drift layer. A depletion layer is formed to a depth of a trench of the vertical trench structure after a depletion layer spreads in a lateral direction between the n-layer and the p-layer when a voltage is applied between a drain and a source. A method for controlling the semiconductor device comprises detecting a voltage value between the drain and the source of the semiconductor device at turn-off and reducing a current value of a gate discharge current discharged from a gate in a first period. The first period starting before the detected voltage value greatly changes.

### CROSS-REFERENCE TO RELATED APPLICATIONS

This application is based upon and claims the benefit of priority from Japanese Patent Application No. 2022-041434, filed on Mar. 16, 2022; the entire contents of which are incorporated herein by reference.

### FIELD

Embodiments described herein relate generally to a semiconductor device and a method for controlling a semiconductor device.

### BACKGROUND

Slew rate technology is known as a method of improving the trade-off between noise reduction and switching loss occurring in the switching operation of a power module.

### BRIEF DESCRIPTION OF THE DRAWINGS

FIG. 1 shows an example of a configuration of a semiconductor device according to a first embodiment.

FIG. 2 is a schematic cross-sectional view showing an example of the structure of the semiconductor according to the first embodiment.

FIG. 3 is a schematic view showing examples of states of the depletion layer of the semiconductor according to the first embodiment.

FIG. 4 is a schematic view showing examples of states of the depletion layer of the semiconductor according to the first embodiment.

FIGS. 5A to 5C show examples of changes of the voltage values, the current value, and the capacitances of the capacitors.

FIG. 6 shows an example of a measurement device according to the first embodiment.

FIG. 7 is a flowchart showing an example of the processing of storing the first period.

FIG. 8 is a flowchart showing an example of processing of slowing the switching operation of the semiconductor device according to the first embodiment.

FIGS. 9A to 9D show an example of simulation results at turn-off according to the first embodiment.

FIGS. 10A to 10D show an example of simulation results at turn-on according to the first embodiment.

FIG. 11 is a flowchart showing an example of processing of slowing the switching operation of the semiconductor device according to a second embodiment.

### DETAILED DESCRIPTION

In general, according to one embodiment, a semiconductor device includes an n-layer and a p-layer arranged in a vertical trench structure in a drift layer. A depletion layer is formed to a depth of a trench of the vertical trench structure after a depletion layer spreads in a lateral direction between the n-layer and the p-layer when a voltage is applied between a drain and a source. A method for controlling the semiconductor device comprises detecting a voltage value between the drain and the source of the semiconductor device at turn-off and reducing a current value of a gate discharge current discharged from a gate in a first period. The first period starting before the detected voltage value greatly changes.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

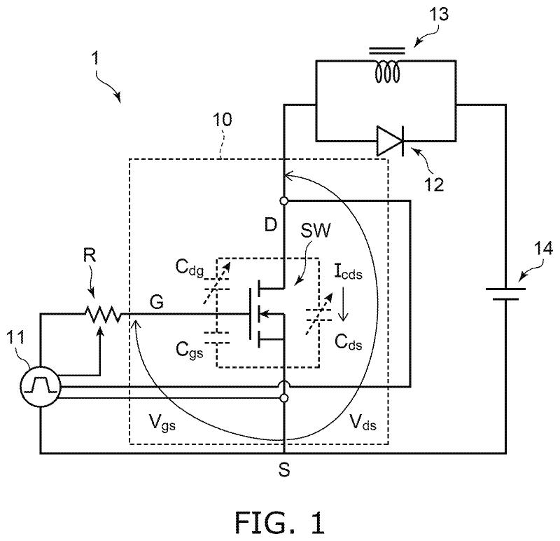

FIG. 1 shows an example of a configuration of a semiconductor device 1.

The semiconductor device 1 includes a semiconductor 10, a driver 11, a diode 12, an inductor 13, a power supply 14, and a gate resistance R.

According to the embodiment, the semiconductor 10 is a SJ-MOSFET (super junction-metal-oxide-semiconductor field-effect transistor). As shown in FIG. 1, a drain D of the semiconductor 10 and the positive side of the power supply 14 are connected with the diode 12 and the inductor 13 interposed. The diode 12 and the inductor 13 are connected in parallel. A source S of the semiconductor 10 is connected between the driver 11 and the negative side of the power supply 14. A gate G of the semiconductor 10 is connected with the driver 11 via the gate resistance R.

The semiconductor 10 includes a switching part SW. Parasitic capacitors are formed around the switching part SW, and specifically, between the drain and the source, between the drain and the gate, and between the gate and the source. Hereinbelow, the parasitic capacitor formed between the drain and the source is taken as a capacitor Cds; the parasitic capacitor formed between the drain and the gate is taken as a capacitor Cdg; and the parasitic capacitor formed between the gate and the source is taken as a capacitor Cgs. The voltage between the drain and the source is taken as a voltage Vds; and the voltage between the gate and the source is taken as a voltage Vgs. The current that flows through the capacitor Cds is taken as a current Icds.

The driver 11 drives the switching operation of the semiconductor 10 by causing a current to flow in the gate G via the gate resistance R by applying a voltage between the gate and the source of the semiconductor 10 at a prescribed interval. According to the embodiment, the driver 11 is configured to change the resistance value of the gate resistance R. For example, the gate resistance R has a configuration in which multiple resistances are connected in parallel, and the multiple resistances each are connectable/disconnectable via switches. The driver 11 changes the magnitude of the resistance value of the gate resistance R by controlling the ON/OFF of each switch. The resistance value of the gate resistance R is reduced by increasing the number of connected switches; and the resistance value of the gate resistance R is increased by reducing the number of connected switches. Thereby, the driver 11 can change the magnitude of the gate charge current flowing in the gate G. Although an example according to the embodiment is described in which the resistance value of the gate resistance R is changed by a configuration in which multiple resistances are connected in parallel, the configuration that changes the resistance value of the gate resistance R is not limited to such a configuration.

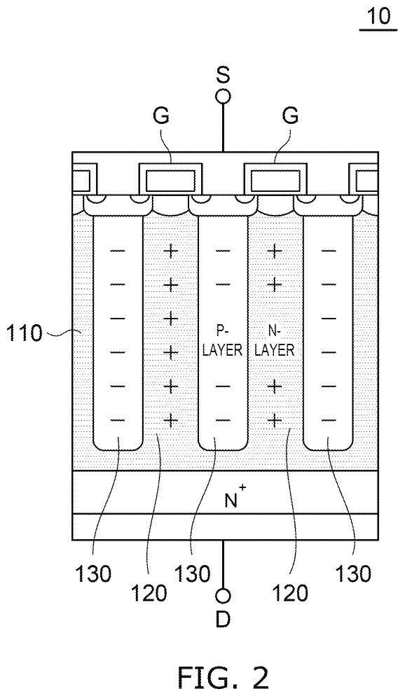

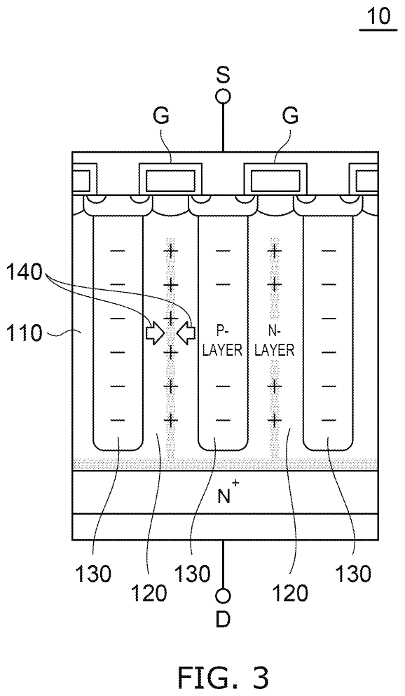

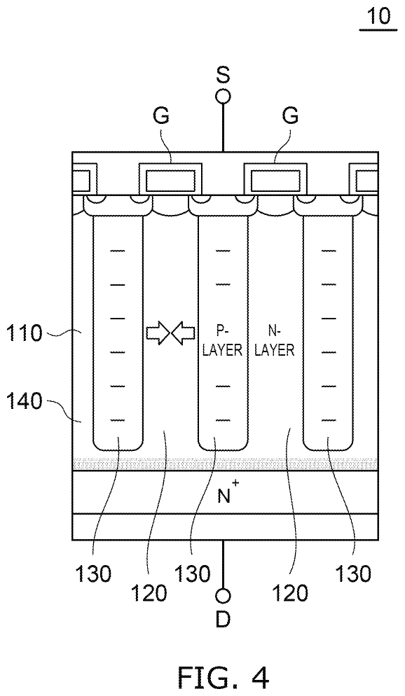

FIG. 2 is a schematic cross-sectional view showing an example of the structure of the semiconductor 10. FIGS. 3 and 4 are schematic views showing examples of states of the depletion layer of the semiconductor 10.

As shown in FIG. 2, the semiconductor 10 includes a drift layer 110; and an n-layer 120 and a p-layer 130 are arranged in a vertical trench structure in the drift layer 110. The gate G is connected to the p-layer 130. In the illustration, the source S is at the upper end side, and the drain D is at the lower end side.

In the semiconductor 10, a depletion layer 140 spreads in the direction (the lateral direction) of the arrows in the illustration between the n-layer 120 and the p-layer 130 as shown in FIG. 3 when a voltage is applied between the drain and the source. Thus, as the depletion layer 140 spreads in the lateral direction between the n-layer 120 and the p-layer 130, eventually, the depletion layer 140 that has the depth of the p-layer 130 (the depth of the vertical trench structure) is formed as shown in FIG. 4. The capacitance of the capacitor Cds abruptly changes in the process of forming the depletion layer 140.

Effects of the formation of the depletion layer 140 will now be described.

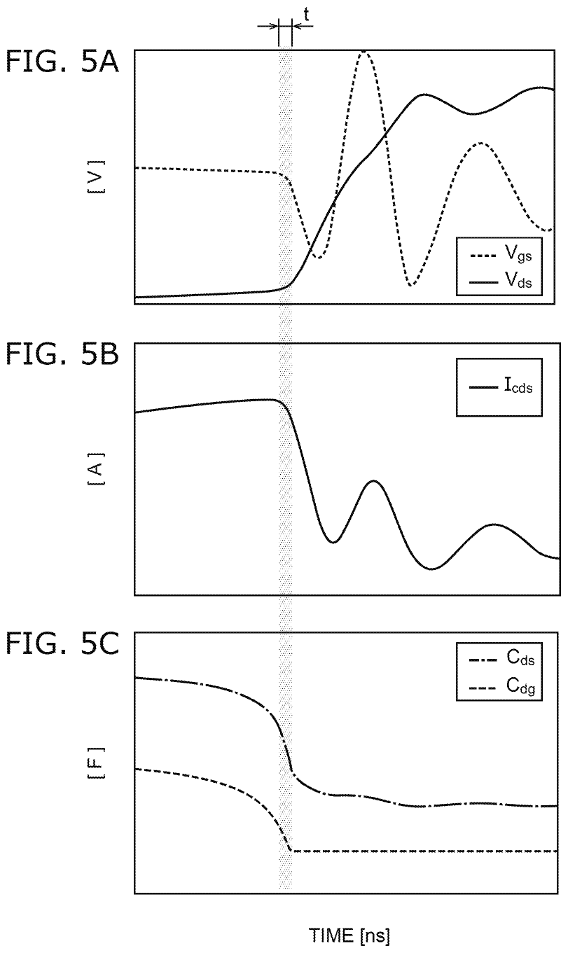

FIGS. 5A to 5C show examples of changes of the voltage values, the current value, and the capacitances of the capacitors. More specifically, FIG. 5A shows an example of changes of the voltage values of the voltages Vgs and Vds; FIG. 5B shows the temporal change of the current value of the current Icds; and FIG. 5C shows the temporal change of the capacitances of the capacitors Cdg and Cds. A period t, i.e., a second period, shows the period in which the depletion layer 140 described above forms.

The vicinity of the period t from turn-off will now be described in detail.

After the discharge of the gate G is started as shown in FIG. 5A, the voltage Vds gradually rises over time. Then, in the period t, an abrupt rise of the voltage value of the voltage Vds starts due to the formation of the depletion layer 140 described above. After the period t has elapsed, the voltage Vds rises at a certain rate. Also, the voltage value of the voltage Vgs gradually falls from a prescribed voltage value. Then, in the period t, the voltage value of the voltage Vgs abruptly falls. After the period t has elapsed, the voltage Vgs falls at a certain rate.

As shown in FIG. 5B, the current value of the current Icds, i.e., the current flowing between the drain and the source, gradually rises from a prescribed value, then abruptly falls in the period t, and then falls at a certain rate.

As shown in FIG. 5C, the capacitances of the capacitors Cds and Cdg both gradually decrease over time. Then, in the period t, the capacitances of the capacitors Cds and Cdg both abruptly decrease. Then, after the period t, the capacitance of the capacitor Cdg becomes constant. The capacitance of the capacitor Cds decreases at a certain rate.

Thus, in the semiconductor device 1, the abrupt changes of the voltage values of the voltages Vds and Vgs, the abrupt changes of the capacitances of the capacitors Cds and Cgs, and the abrupt change of the current value of the current Icds occur at the timing of the formation of the depletion layer 140 described above.

Thus, noise is generated in the semiconductor device 1 by the abrupt voltage value, capacitance, and current value changes in the period t. To prevent such noise, the semiconductor device 1 of the embodiment performs processing to slow the switching operation of the switching part SW by reducing the gate discharge current in a period T, i.e., a first period. According to the embodiment, the period T is a certain period that includes the period t. More specifically, the period T is started slightly before the start of the period t and ends slightly after the end of the period t.

The processing of slowing the switching operation of the switching part SW in the period T including the period t at turn-off will now be described.

First, processing of storing, in the driver 11, the period T for performing the processing of slowing the switching operation will be described. Here, according to the embodiment, the period T is the period at turn-off from when the voltage Vds between the drain and the source becomes a first voltage value to when the voltage Vds becomes a second voltage value.

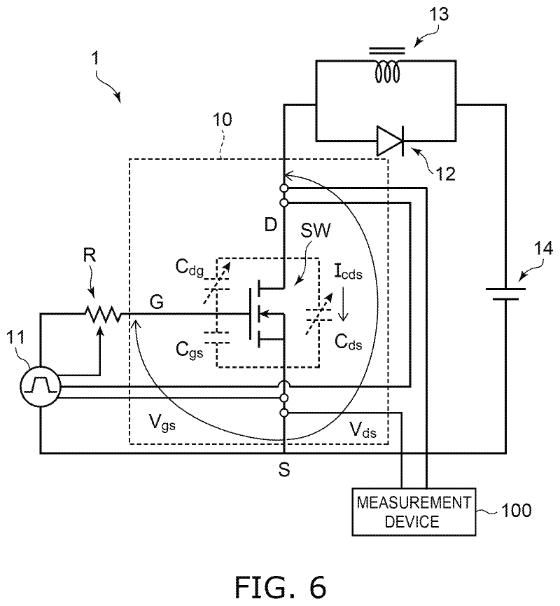

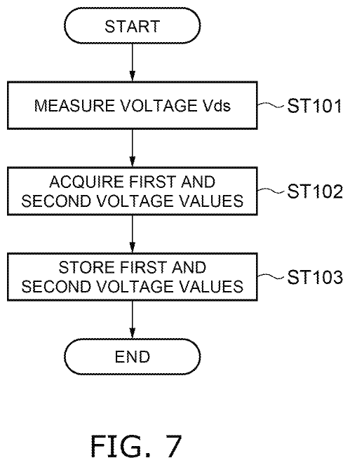

FIG. 7 is a flowchart showing an example of the processing of storing the first period. In this processing, for example, as shown in FIG. 6, the processing of measuring the voltage Vds is performed using a prescribed measurement device 100 of the semiconductor device 1. It is sufficient for the measurement device 100 to be capable of measuring the voltage Vds between the drain and the source of the semiconductor device 1.

First, as shown in FIG. 7, the measurement device 100 measures the voltage Vds at turn-off (ST101). For example, the measurement is performed by using the measurement device 100 to actually measure the voltage Vds by actually operating the semiconductor device 1 before shipping the semiconductor device 1.

Then, the measurement device 100 acquires the first voltage value and the second voltage value (ST102). The period t in which the voltage value abruptly changes is acquired from the actual measured value of the voltage Vds measured by the measurement device 100; and the period T is set to include the period t. The voltage value of the voltage Vds between the drain and the source at the start of the period T is taken as the first voltage value. The end of the period T is the voltage value of the voltage Vds at the end of the period T that is set. The voltage value at the end of the period T is taken as the second voltage value (which is greater than the first voltage value).

Then, for example, the first voltage value and the second voltage value that are measured by the measurement device 100 are stored in prescribed memory of the driver 11 of the semiconductor device 1 when manufacturing the driver 11 (ST103). Thereby, the driver 11 can acquire the period T in which the switching operation of the switching part SW is slowed. When the period T of the semiconductor device 1 has been pre-acquired, it is sufficient to use a prescribed device to store the first voltage value and the second voltage value in the driver 11 of the semiconductor device 1 without performing the processing of steps ST101 and ST102 described above.

Instead of the voltage value of the voltage Vds, the period T may be set based on time. In other words, when the period T is set, a first time from turn-off to the start of the period T is set; a second time at the end of the period T is set; and the switching operation of the switching part SW may be slowed by using, as the period T, the time from the timing of detecting the first time to the timing of detecting the second time.

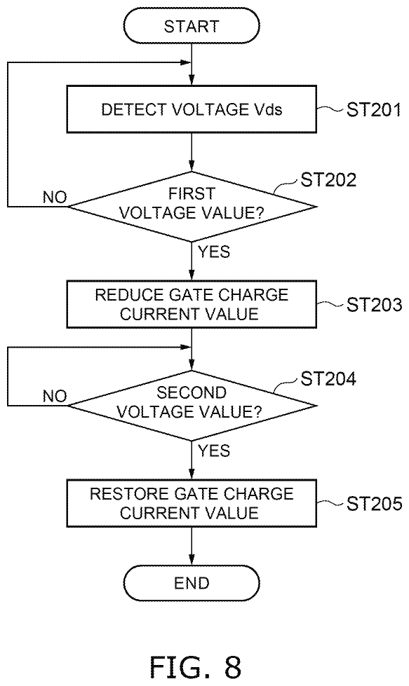

FIG. 8 is a flowchart showing an example of processing of slowing the switching operation of the semiconductor device 1 in the period T described above at turn-off.

As shown in FIG. 8, the driver 11 detects a voltage value Vds (ST201).

Then, the driver 11 determines whether or not the detected voltage value Vds is the first voltage value (ST202). When the voltage value Vds is determined not to be the first voltage value (ST202: NO), the processing returns to step ST201. That is, the processing of detecting the voltage value Vds is continued.

When the voltage value of the detected voltage value Vds is determined to be the first voltage value (ST202: YES), the driver 11 reduces the gate discharge current (ST203). According to the embodiment, for example, the driver 11 increases the resistance of the gate resistance R by operating the multiple switches described above to reduce the number of connected switches. The current value of the gate discharge current flowing into the gate G is reduced thereby, and the switching operation of the switching part SW is slowed.

Then, the driver 11 determines whether or not the voltage value of the detected voltage Vds is the second voltage value (ST204). When the voltage value is determined not to be the second voltage value (ST204: NO), the processing returns to step ST204. Thereby, the state in which the gate discharge current is small is continued until the second voltage value is detected, that is, until the end of the period T. That is, the state in which the switching operation of the switching part SW is slowed is continued.

When the voltage value is determined to be the second voltage value (ST204: YES), the driver 11 returns the gate discharge current to the original current (ST205). For example, the driver 11 reduces the resistance of the gate resistance R by increasing the number of connected switches to the original state by operating the multiple switches described above. Thereby, the current value of the gate discharge current flowing into the gate G returns to the original magnitude; and the switching operation of the switching part SW speeds up and returns to the original switching operation.

Thus, the semiconductor device 1 performs processing at turn-off to slow the switching operation of the switching part SW during the period T; and the period T includes the period t and starts slightly before the start of the period t at which the voltage value of the voltage Vds between the drain and the source abruptly changes and the depletion layer 140 is formed.

Simulation results will now be described.

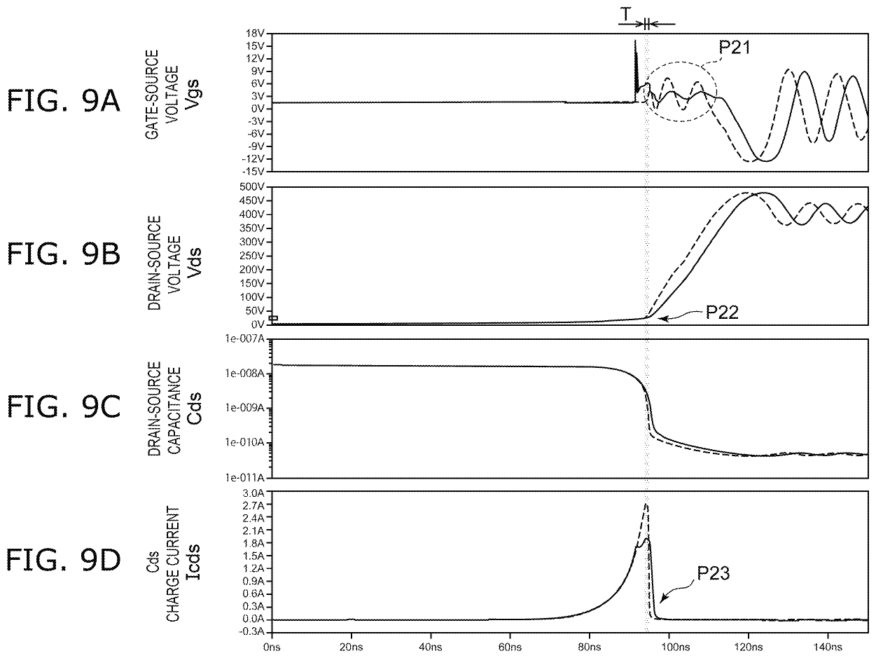

FIGS. 9A to 9D show an example of simulation results. More specifically, FIG. 9A shows the change of the voltage value of the voltage Vgs, i.e., the gate-source voltage, at turn-off. FIG. 9B shows the change of the voltage value of the voltage Vds, i.e., the drain-source voltage. FIG. 9C shows the change of the capacitance of the capacitor Cds, i.e., the drain-source capacitance. FIG. 9D shows the change of the current value of the current Icds, i.e., the charge current of the capacitor Cds.

In FIGS. 9A to 9D, the broken line is the simulation result when the switching operation according to the embodiment is not performed; and the solid line is the simulation result when the switching operation according to the embodiment is performed.

First, an example of the simulation result (the broken line) when the switching operation according to the embodiment is not performed will be described.

The voltage Vds between the drain and the source gradually increases over time at turn-off. However, the voltage value of the voltage Vds abruptly increases in the period T. As described above, this is because the depletion layer 140 of the semiconductor 10 is formed. Due to this effect, the magnitude of the voltage value of the voltage Vgs between the gate and the source oscillates in the range shown by P21 after the period T1. The oscillation causes noise.

The capacitance of the capacitor Cds between the drain and the source abruptly decreases due to the abrupt change of the voltage Vds in the period T. Therefore, the current Icds of the capacitor Cds that had been rising abruptly decreases. The decrease of the current Icds is accompanied by an abrupt decrease of the temporal change dI/dt of the current. Therefore, a voltage oscillation defined by dI/dt×Ls (Ls: the parasitic inductance in the circuit) occurs.

Thus, because the semiconductor 10 is a SJ-MOSFET, due to the structural reasons described with reference to FIGS. 2 to 4, noise is generated at turn-off at the timing at which the capacitance of the capacitor Cds greatly changes.

An example of the simulation result (the solid line) when the switching operation according to the embodiment is performed will now be described. According to the embodiment, the first voltage value is set to 20 V; the second voltage value is set to 30 V; and the processing of slowing the switching operation of the switching part SW in the period T is performed.

At turn-off, the voltage Vds between the drain and the source similarly increases gradually over time. However, in the period T shown by P22 in which the voltage Vds is set to 20 V to 30 V, the abruptness of the voltage value Vds is suppressed compared with the broken line. In such a case, compared with the broken line in the range shown by P21, the magnitude of the oscillation of the voltage Vgs between the gate and the source is suppressed. That is, the voltage value oscillations that cause noise are suppressed by performing the switching operation of the embodiment.

Although the capacitance of the capacitor Cds between the drain and the source decreases according to the abrupt change of the voltage Vds in the period T, the abruptness is suppressed compared with the broken line. Therefore, although the current value of the current Icds of the capacitor Cds that had been rising decreases, the abruptness of the change of the current value of the current Icds is suppressed compared with the broken line. That is, as shown by P23, the temporal change dI/dt of the current value of the current Icds also is moderate. Therefore, the change of the voltage oscillation defined by dI/dt×Ls also is reduced.

Thus, according to the semiconductor device 1, the switching operation of the semiconductor 10 can be slowed regardless of the current value in the period T, e.g., while the detected value of the voltage Vds between the drain and the source is between the first voltage value and the second voltage value. Thereby, the semiconductor device 1 can suppress the noise and the switching loss when the voltage value of the voltage Vds between the drain and the source greatly changes at turn-off due to structural reasons. Accordingly, the semiconductor device 1 can improve the trade-off between switching loss and noise.

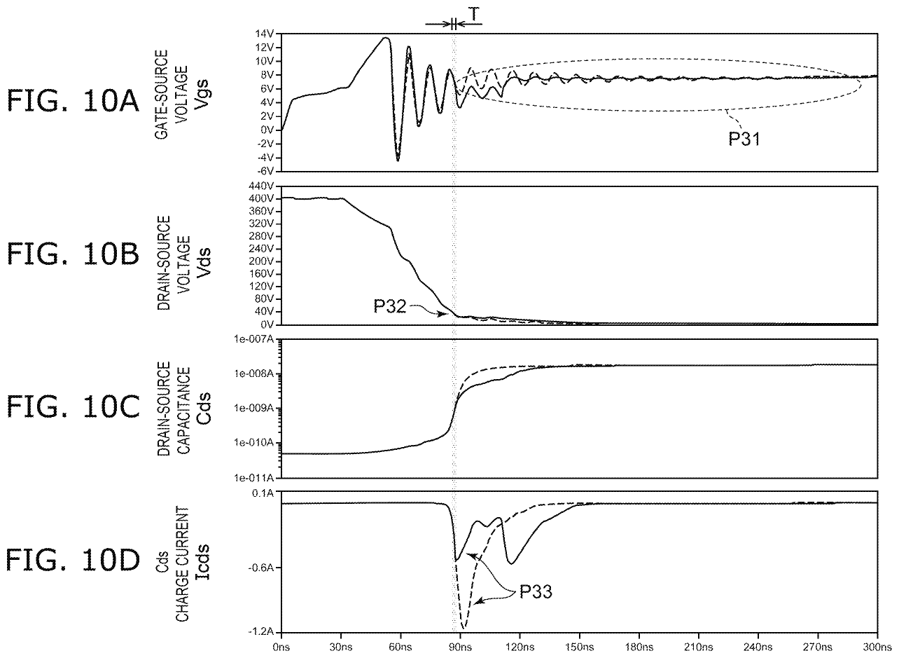

Although processing at turn-off is described in the embodiment described above, similar processing can also be performed at turn-on. FIGS. 10A to 10D show an example of simulation results at turn-on. FIG. 10A shows the change of the voltage value of the voltage Vgs, i.e., the gate-source voltage. FIG. 10B shows the change of the voltage value of the voltage Vds, i.e., the drain-source voltage. FIG. 10C shows the change of the capacitance of the capacitor Cds, i.e., the drain-source capacitance. FIG. 10D shows the change of the current value of the current Icds, i.e., the charge current of the capacitor Cds.

In FIGS. 10A to 10D, similarly to the simulation result of FIGS. 9A to 9D, the broken line is a simulation result when the switching operation according to the embodiment is not performed; and the solid line is a simulation result when the switching operation according to the embodiment is performed.

As shown in FIGS. 10A to 10D, when the switching operation of the embodiment is not performed, an abrupt change of the voltage Vds between the drain and the source occurs as shown by P32 in the period T (a third period) including the period t, accompanied by an abrupt change of the capacitance of the capacitor Cds as well. As shown by P33, the current Icds also is abruptly changed thereby. As a result, as shown by P31, the change of the voltage oscillation of the voltage Vgs increases, and noise is generated.

On the other hand, when the switching operation of the embodiment is performed, compared with when the switching operation is not performed in the period T as shown by P32, the change of the voltage Vds between the drain and the source and the change of the capacitance of the capacitor Cds are suppressed. As shown by P33, the change of the abruptness of the current Icds also is suppressed thereby. As a result, as shown by P31, the change of the voltage oscillation of the voltage Vgs is suppressed, and the noise is suppressed.

Thus, in addition to turn-off, the semiconductor device 1 can provide effects similar to turn-off by performing the processing of slowing the switching operation in the period T at turn-on as well.

### Second Embodiment

A second embodiment differs from the first embodiment described above in that the first voltage value and the second voltage value are acquired by a first switching operation; and the second and subsequent switching operations are performed based on the first and second voltage values that are acquired. The processing of performing the switching operation will now be described in detail. The same configurations as the first embodiment described above are marked with the same reference numerals; and a detailed description is omitted.

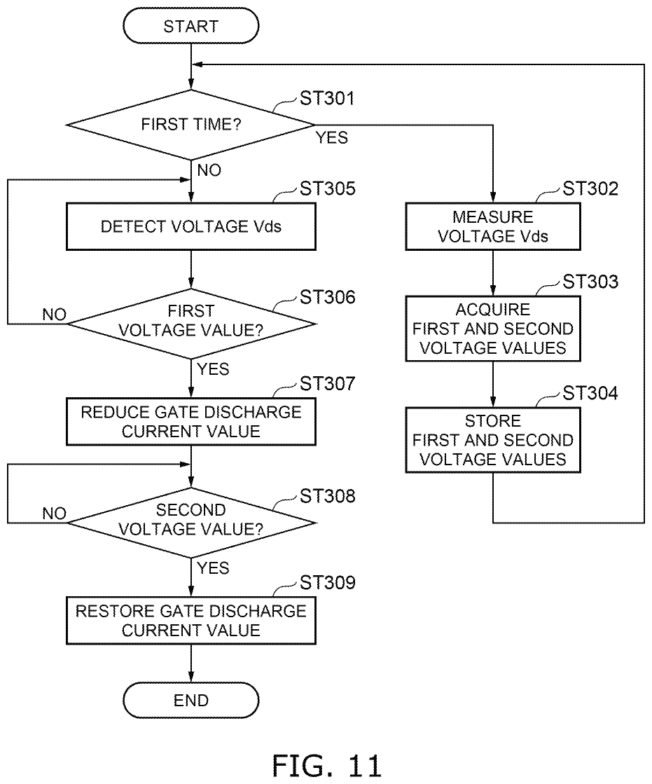

FIG. 11 is a flowchart showing an example of processing of slowing the switching operation of the semiconductor device 1 at turn-off in the certain period described above.

As shown in FIG. 11, the driver 11 determines whether or not the switching operation is the first switching operation (ST301). When the switching operation is determined to be the first switching operation (ST301: YES), the driver 11 performs the processing of steps ST302 to ST304. The processing of steps ST302 to ST304 acquires the first voltage value and the second voltage value in the first switching operation. The processing of steps ST302 to ST304 is performed by the driver 11 instead of the measurement device 100 described above; otherwise, the processing of steps ST302 to ST304 is the same processing as steps ST101 to ST103.

The driver 11 measures the voltage value of the voltage Vds between the drain and the source (ST302), acquires the first voltage value and the second voltage value (ST303), and stores the first voltage value and the second voltage value (ST304). Thereby, the first voltage value and the second voltage value are stored in prescribed memory in the driver 11.

On the other hand, when the switching operation is determined not to be the first switching operation (ST301: NO), the driver 11 performs the processing of steps ST305 to ST309. The processing of steps ST305 to ST309 slows the switching operation during the period T by utilizing the first and second voltage values stored in the first switching operation. The processing of steps ST305 to ST309 is the same processing as the processing of steps ST201 to ST205 described above.

The driver 11 detects the voltage value of the voltage Vds between the drain and the source (ST305) and reduces the gate discharge current value (ST307) when the voltage value is determined to be the first voltage value (ST306: YES). Thereby, the switching operation of the switching part SW is slowed during the period T, i.e., the certain period that starts slightly before the voltage Vds greatly changes. Then, when the voltage Vds is determined to be the second voltage value (ST308: YES), the driver 11 returns the gate discharge current value to the original current value (ST309), and this processing ends.

According to the semiconductor device 1 of the embodiment, effects similar to those of the semiconductor device 1 of the first embodiment can be provided. Furthermore, the processing of slowing the switching operation of the switching part SW in the period T, i.e., the certain period starting slightly before the voltage value of the voltage Vds between the drain and the source greatly changes, can be performed by the semiconductor device 1 without utilizing the measurement device 100 described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A method for controlling a semiconductor device,
the semiconductor device including an n-layer and a p-layer arranged in a vertical trench structure in a drift layer,
a depletion layer being formed to a depth of a trench of the vertical trench structure after a depletion layer spreads in a lateral direction between the n-layer and the p-layer when a voltage is applied between a drain and a source,
the method comprising:
detecting a voltage value between the drain and the source of the semiconductor device at turn-off; and
reducing a current value of a gate discharge current discharged from a gate in a first period,
the first period starting before the detected voltage value greatly changes.

2. The method according to claim 1, wherein
the current value of the gate discharge current is reduced by increasing a gate resistance value of the gate.

3. The method according to claim 1, wherein
the first period includes a second period in which the depletion layer is formed to the depth of the trench.

4. The method according to claim 1, further comprising:
before the detecting of the voltage value, storing a first voltage value detected at a start of the first period,
the current value of the gate discharge current being reduced from when the first voltage value is detected.

5. The method according to claim 1, further comprising:
before the detecting of the voltage value, storing a second voltage value detected at an end of the first period,
the first period ending when the second voltage value is detected.

6. The method according to claim 1, further comprising:
acquiring a first voltage value at a first turn-off based on a detection result of the detecting of the voltage value, the first voltage value being detected at a start of the first period; and
reducing the current value of the gate discharge current in the first period at second and subsequent turn-offs,
the first period starting from when the first voltage value is detected.

7. The method according to claim 1, further comprising:
in addition to the reducing of the current value of the gate discharge current at turn-off, reducing a current value of a gate charge current in a third period at turn-on,
the gate charge current charging the gate,
the third period starting before the detected voltage value greatly changes.

8. A semiconductor device, comprising:
a drift layer;
a p-layer and an n-layer arranged in a vertical trench structure in the drift layer, a depletion layer being formed to a depth of a trench of the vertical trench structure after a depletion layer spreads in a lateral direction between the n-layer and the p-layer when a voltage is applied between a drain and a source at turn-off; and
a controller detecting a voltage value between the drain and the source and reducing a current value of a gate discharge current in a first period at turn-off,
the gate discharge current discharging from a gate,
the first period starting before the detected voltage value greatly changes.
